(19) United States
(12) Patent Application Publication
(10) Pub. No.: US 2024/0141484 A1
(43) Pub. Date: May 2, 2024

(54) SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Yasuaki KOMAE, Toyama-shi (JP); Hiroki OKAMIYA, Toyama-shi (JP); Koichi HONDA, Toyama-shi (JP)

(73) Assignee: Kokusai Electric Corporation, Tokyo (JP)

(21) Appl. No.: 18/482,324

(22) Filed: Oct. 6, 2023

(30) Foreign Application Priority Data
Oct. 31, 2022 (JP) 2022-173989

(51) Int. Cl. C23C 16/44; C23C 16/458; H01L 21/67; H01L 21/673

(52) U.S. Cl. CPC C23C 16/4411; C23C 16/4408; C23C 16/4583; H01L 21/67017; H01L 21/6732

(57) ABSTRACT

There is provided a technique that includes: a process vessel in which a substrate is processed; a lid capable of closing an opening provided at a lower portion of the process vessel; an elevator capable of elevating and lowering the lid; a heat insulator provided between the lid and the substrate and comprising a case of a cylindrical shape with a closed upper end; and a cooling gas supplier configured to purge an inside of the heat insulator by supplying a purge gas through a discharge port in the case while the opening is closed by the lid, and to cool the heat insulator by supplying a cooling gas through the discharge port while the opening is not closed by the lid.

### CROSS-REFERENCE TO RELATED PATENT APPLICATION

This non-provisional U.S. patent application is based on and claims priority under 35 U.S.C. § 119 of Japanese Patent Application No. 2022-173989, filed on Oct. 31, 2022, in the Japanese Patent Office, the entire contents of which are hereby incorporated by reference.

### BACKGROUND

### 1. Field

The present disclosure relates to a substrate processing apparatus, a substrate processing method, a method of manufacturing a semiconductor device and a non-transitory computer-readable recording medium.

### 2. Related Art

In a method of manufacturing a semiconductor device, a substrate processing apparatus such as a vertical type substrate processing apparatus may be used as an apparatus configured to process a substrate. For example, the substrate processing apparatus may include a boat in which the substrate is accommodated and a process chamber (or a plurality of process chambers) in which the substrate is processed. For example, the substrate is processed by and sequentially transferring the boat into and out of each process chamber.

The boat may include a heat insulator (which is a heat insulating structure) at a bottom thereof to maintain an inner temperature of the process chamber to a desired temperature. In a cooling step for the substrate, a cooling gas may be supplied (sprayed) onto the boat to cool the substrate and the heat insulator. Since a heat capacity of the heat insulator is greater than that of the substrate, it is preferable to set a cooling time in the cooling step in accordance with a cooling time of the heat insulator.

### SUMMARY

According to the present disclosure, there is provided a technique capable of shortening a cooling time of a heat insulator.

According to an aspect of the present disclosure, there is provided a technique that includes: a process vessel in which a substrate is processed; a lid capable of closing an opening provided at a lower portion of the process vessel; an elevator capable of elevating and lowering the lid; a heat insulator provided between the lid and the substrate and comprising a case of a cylindrical shape with a closed upper end; and a cooling gas supplier configured to purge an inside of the heat insulator by supplying a purge gas through a discharge port in the case while the opening is closed by the lid, and to cool the heat insulator by supplying a cooling gas through the discharge port while the opening is not closed by the lid.

### BRIEF DESCRIPTION OF THE DRAWINGS

FIG. 1 is a diagram schematically illustrating a vertical cross-section of an example of a substrate processing apparatus according to one or more embodiments of the present disclosure.

FIG. 2 is a diagram schematically illustrating a vertical cross-section of an example of a process furnace of the substrate processing apparatus according to the embodiments of the present disclosure.

FIG. 3 is a diagram schematically illustrating a vertical cross-section of an example of a heat insulator of the substrate processing apparatus according to the embodiments of the present disclosure.

FIG. 4 is a block diagram schematically illustrating a configuration of a controller and related components of the substrate processing apparatus according to the embodiments of the present disclosure.

FIG. 5 is a flow chart schematically illustrating a substrate processing according to the embodiments of the present disclosure.

FIG. 6 is a diagram schematically illustrating a perspective view of a modified example of a supply pipe of the substrate processing apparatus according to the embodiments of the present disclosure.

### DETAILED DESCRIPTION

<Embodiments of Present Disclosure>

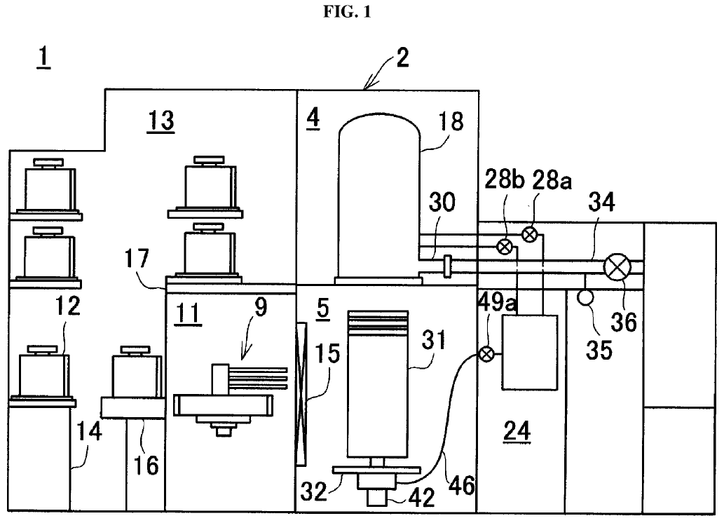

Hereinafter one or more embodiments (also simply referred to as “embodiments”) of the technique of the present disclosure will be described mainly with reference to FIGS. 1 through 5. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, the same or corresponding reference numerals represent the same or corresponding components in the drawings, and redundant descriptions related thereto will be omitted.

A substrate processing apparatus according to the present embodiments is configured as a vertical type substrate processing apparatus (hereinafter, also simply referred to as a “substrate processing apparatus”) 1 capable of performing a substrate processing such as a heat treatment process. The substrate processing is performed as a part of a manufacturing process in a method of manufacturing a semiconductor device.

As shown in FIG. 1, the substrate processing apparatus 1 includes a process module 2, and the process module 2 includes a housing (or a frame) with an approximately rectangular parallelepiped outline. The process module 2 is constituted by a process furnace 4 and a transfer chamber 5.

The transfer chamber 5 is arranged below the process furnace 4, and a transport chamber 11 is arranged adjacent to a front portion of the transfer chamber 5. The transport chamber 11 includes a housing with an approximately rectangular parallelepiped outline. The transport chamber 11 may be provided with a transfer structure (which is a transfer device) 9 capable of transferring a wafer 8 serving as a substrate. A storage chamber 13 in which a plurality of pods including a pod (FOUP: Front Opening Unified Pod) 12 is connected to a front portion of the transport chamber 11. Hereinafter, the plurality of pods including the pod 12 may also be simply referred to as “pods 12”. Each of the pods 12 is configured such that a plurality of wafers including the wafer 8 can be stored in the pod 12. Hereinafter, the plurality of wafers including the wafer 8 may also be simply referred to as “wafers 8”. An outer diameter of each of the storage chamber 13, the process module 2 and the transport chamber 11 is set based on a polyhedron constituted by mutually orthogonal planes. Further, each of the storage chamber 13, the process module 2 and the transport chamber 11 is detachable, and appropriate airtightness is secured on connection portions thereof. An I/O port (input/output port) 14 is provided on a front surface of the storage chamber 13 such that the pod 12 can be transferred (loaded) into or transferred (unloaded) from the substrate processing apparatus 1 through the I/O port 14. A mounting table (which is a placement table) 16 is provided adjacent to the transport chamber 11 such that the wafers 8 can be transferred into the transport chamber 11 from the pod 12 placed on the mounting table 16.

On a boundary wall (adjacent surface) between the transfer chamber 5 and the transport chamber 11, a gate valve 15 is provided such that the wafers 8 can be transferred between the transfer chamber 5 and the transport chamber 11 through the gate valve 15. Pressure detectors (not shown) are provided in the transport chamber 11 and the transfer chamber 5, respectively. An inner pressure of the transport chamber 11 may be set to be lower than an inner pressure of the transfer chamber 5. Further, oxygen concentration detectors (not shown) are provided in the transport chamber 11 and the transfer chamber 5, respectively. Oxygen concentrations in the transport chamber 11 and the transfer chamber 5 may be maintained to be lower than an oxygen concentration in an outer atmosphere. A clean air supplier (which is a clean air supply structure) 17 through which clean air is supplied into the transport chamber 11 is provided at a ceiling of the transport chamber 11. The clean air supplier 17 is configured such that the clean air such as an inert gas is circulated in the transport chamber 11 through the clean air supplier 17. By circulating the inert gas and purging an inner portion of the transport chamber 11 with the inert gas, it is possible to maintain an inner atmosphere of the transport chamber 11 at a clean atmosphere. With such a configuration, it is possible to prevent (or suppress) a substance such as particles in the transfer chamber 5 from entering the transport chamber 11. It is also possible to prevent (or suppress) a natural oxide film from being formed on the wafer 8 in the transport chamber 11 or in the transfer chamber 5.

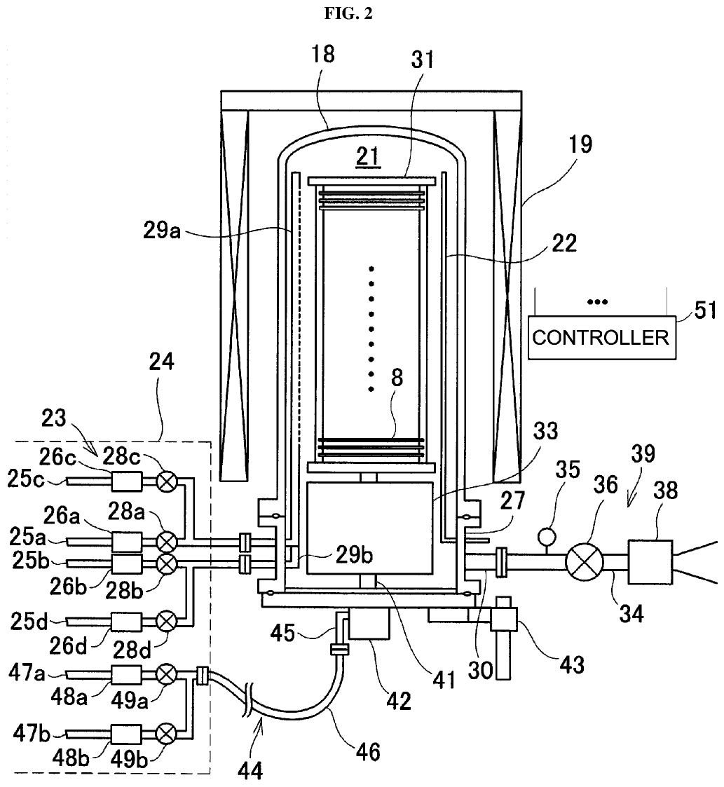

As shown in FIG. 2, the process furnace 4 includes a process vessel 18 (also referred to as a “reaction tube 18”) of a cylindrical shape and a heater 19 serving as a heating structure (heating apparatus) installed around an outer circumference of the reaction tube 18. For example, the reaction tube 18 is made of a material such as quartz (SiO₂) and silicon carbide (SiC). A process chamber 21 in which the wafer 8 serving as the substrate is processed is provided in the reaction tube 18. Further, a temperature detector 22 serving as a temperature meter is installed in the reaction tube 18. For example, the temperature detector 22 is vertically installed along an inner wall of the reaction tube 18.

A gas used for the substrate processing is supplied into the process chamber 21 through a gas supply structure (which is a gas supply system or a gas supplier) 23. The gas supplied through the gas supply structure 23 may be changed depending on a type of a film to be formed. For example, according to the present embodiments, the gas supply structure 23 includes a source gas supplier (which is a source gas supply system or a source gas supply structure), a reactive gas supplier (which is a reactive gas supply system or a reactive gas supply structure) and an inert gas supplier (which is an inert gas supply system or an inert gas supply structure). The gas supply structure 23 is accommodated in a supply box 24 (also referred to as a “gas box” 24) described later.

The source gas supplier includes a gas supply pipe 25a. A mass flow controller (MFC) 26a serving as a flow rate controller (flow rate control structure) and a valve 28a serving as an opening/closing valve are sequentially provided at the gas supply pipe 25a in this order from an upstream side to a downstream side of the gas supply pipe 25a in a gas flow direction. The gas supply pipe 25a is connected to a nozzle 29a passing through a side wall of a manifold 27. The nozzle 29a is installed along an up-and-down direction (vertical direction) within the reaction tube 18. The nozzle 29a is provided with a plurality of supply holes opened toward the wafers 8 accommodated in a boat 31 serving as a substrate retainer. A source gas is supplied to the wafers 8 through the plurality of supply holes of the nozzle 29a.

Similarly, a reactive gas is supplied to the wafers 8 through the reactive gas supplier via a gas supply pipe 25b, an MFC 26b, a valve 28b and a nozzle 29b, and the inert gas is supplied to the wafers 8 through the inert gas supplier via gas supply pipes 25c and 25d, MFCs 26c and 26d, valves 28c and 28d, and the nozzles 29a and 29b. For example, the gas supply pipes 25a, 25b, 25c and 25d may be collectively or individually referred to as a “gas supply pipe 25”, the MFCs 26a, 26b, 26c and 26d may be collectively or individually referred to as an “MFC 26”, the valves 28a, 28b, 28c and 28d may be collectively or individually referred to as a “valve 28”, and the nozzles 29a and 29b may be collectively or individually referred to as a “nozzle 29”.

The manifold 27 of a cylindrical shape is connected to a lower end opening of the reaction tube 18 via a seal (which is a sealing structure) such as an O-ring to support a lower end of the reaction tube 18. A lower end opening of the manifold 27 is arranged corresponding to a ceiling of the transfer chamber 5. The lower end opening of the manifold 27 communicates with the transfer chamber 5, and may be opened and closed by a lid 32 of a disk shape. A seal such as an O-ring is provided on an upper surface of the lid 32 to airtightly seal (or close) the reaction tube 18 from the outer atmosphere (outside air). A heat insulator (which is a heat insulating structure) 33 is placed on the lid 32. For example, the reaction tube 18 and the manifold 27 may also be collectively referred to as the “reaction tube 18” or the “process vessel 18”. In such a case, the lower end opening of the reaction tube 18 is closed by the lid 32.

The manifold 27 is provided with an exhaust port 30 extending in a direction orthogonal to an axial center of the manifold 27, that is, in a direction orthogonal to a tube axis of the reaction tube 18, and an exhaust pipe 34 is provided via the exhaust port 30. A booster pump 38 serving as a vacuum exhaust apparatus is connected to the exhaust pipe 34 via a pressure sensor 35 serving as a pressure detector (which is a pressure detecting structure) capable of detecting an inner pressure of the process chamber 21 and a conductance variable valve 36 serving as a pressure regulator (which is a pressure adjusting structure). For example, the conductance variable valve 36 is constituted by a two-stage valve configured by connecting two valves (that is, an APC (Automatic Pressure Controller) valve and a gate valve) in series. For example, the APC valve is constituted by a butterfly valve capable of being opened with a channel cross-sectional area equal to or greater than a cross-sectional area of the exhaust pipe 34. With such a configuration, it is possible to set the inner pressure of the process chamber 21 to a process pressure corresponding to a processing such as the substrate processing. An exhauster (which is an exhaust structure or an exhaust system) 39 is constituted mainly by the exhaust pipe 34, the pressure sensor 35 and the conductance variable valve 36. The exhauster 39 may further include the booster pump 38.

The process chamber 21 is configured such that the boat 31 serving as the substrate retainer is accommodated in the process chamber 21. For example, the boat 31 is capable of holding (supporting or accommodating) the wafers 8 (for example, 10 wafers to 150 wafers) and is formed into a shelf shape vertically in a multistage manner. The boat 31, which holds the wafers 8 within the reaction tube 18 is supported above the heat insulator 33 by a rotating shaft 41 penetrating through the lid 32 and the heat insulator 33. The rotating shaft 41 is hollow, and is rotatably supported by a rotator 42 provided below the lid 32. The rotating shaft 41 is configured to be capable of being rotated by the rotator 42 while hermetically sealing an inside (inner space) of the reaction tube 18. The lid 32 is vertically driven by a boat elevator 43 disposed in the transfer chamber 5 to serve as an elevating structure. Thereby, the boat 31 and the lid 32 are elevated or lowered together such that the boat 31 is loaded into or unloaded out of the reaction tube 18. When the boat 31 is lowered, the boat 31 is inserted into the transfer chamber 5. In such a state, a transfer operation for the wafer 8 to the boat 31 is performed in the transfer chamber 5.

A cooling gas and a purge gas are introduced (supplied) into the heat insulator 33 through a cooling gas supplier (which is a cooling gas supply structure or a cooling gas supply system) 44. For example, the cooling gas supplier 44 includes: an introducer (which is a gas introducer or a gas introduction structure) 45; a supply pipe 46 connected to the introducer 45; a gas supply pipe 47a connected to the supply pipe 46; and a gas supply pipe 47b branching from the gas supply pipe 47a.

A mass flow controller (MFC) 48a serving as a flow rate controller (flow rate control structure) and a valve 49a serving as a control valve are sequentially provided at the gas supply pipe 47a in this order from an upstream side to a downstream side of the gas supply pipe 47a in the gas flow direction. A mass flow controller (MFC) 48b serving as a flow rate controller (flow rate control structure) and a valve 49b serving as a control valve are sequentially provided at the gas supply pipe 47b in this order from an upstream side to a downstream side of the gas supply pipe 47b in the gas flow direction. The gas supply pipes 47a and 47b, the MFCs 48a and 48b and valves 49a and 49b are (accommodated (housed) in the gas box 24. The cooling gas supplier 44 may be a part of the gas supply structure 23. Further, the gas supply pipes 47a and 47b may be collectively or individually referred to as a “gas supply pipe 47”, the MFCs 48a and 48b may be collectively or individually referred to as an “MFC 48”, and the valves 49a and 49b may be collectively or individually referred to as a “valve 49”.

The introducer 45 may include an introduction pipe 45a installed along an up-and-down direction (vertical direction) of the rotator 42 and a port 45b connected to the introduction pipe 45a provided on a side portion of the rotator 42. Therefore, the introduction pipe 45a is fixedly provided with respect to the rotator 42, and is configured to move vertically together with the lid 32 by the boat elevator 43. Alternatively, the introduction pipe 45a may be fixedly provided on the lid 32.

The introduction pipe 45a communicates with an inside (inner space) of the rotator 42 through the port 45b, and the rotator 42 communicates with an inside (inner space) of the heat insulator 33 through a hole 45c vertically penetrating the rotating shaft 41. Since the introducer 45 is constituted by the introduction pipe 45a, the port 45b, a space between the inside of the rotator 42 and the rotating shaft 41 and the hole 45c penetrating the rotating shaft 41, the rotating shaft 41 is configured as a part of the introducer 45. Therefore, an inside (inner space) of the rotating shaft 41 (the hole 45c) and the inside of the heat insulator 33 are fluidically in communication with each other, and an inside of the heat insulator 33 and the inside of the rotator 42 are fluidically in communication with each other through the hole 45c.

For example, the supply pipe 46 is made of a material such as a synthetic resin containing fluorine with a sufficient flexibility. Further, the supply pipe 46 extends in a predetermined length and is connected to the introduction pipe 45a and the gas supply pipe 47a in a state where the supply pipe 46 is bent. According to the present embodiments, the supply pipe 46 extends in a sufficient length such that a connection state with the introduction pipe 45a and the gas supply pipe 47a is capable of being maintained regardless of a position of the boat 31. Therefore, even when the introducer 45 is elevated or lowered in the vertical direction together with the boat 31, fluid communications among the introducer 45, the supply pipe 46 and the gas supply pipe 47a can be maintained. In such a case, a first end of the supply pipe 46 facing the gas supply pipe 47a (that is, an upstream end of the supply pipe 46) serves as a fixed end which is unmovable, and a second end of the supply pipe 46 facing the introduction pipe 45a (that is, a downstream end of the supply pipe 46) serves a movable end which is elevated or lowered together with the boat 31.

The gas supply pipe 47a is connected to a cooling gas supply source (not shown), and the cooling gas is supplied into the heat insulator 33 through the gas supply pipe 47a, the supply pipe 46 and the introducer 45. The gas supply pipe 47b is connected to a purge gas supply source (not shown), and the purge gas is supplied into the heat insulator 33 through the gas supply pipe 47b, the gas supply pipe 47a, the supply pipe 46 and the introducer 45. Therefore, by opening and closing the valves 49a and 49b serving as the control valves, it is possible to perform a turn-on and turn-off operation (that is, an ON/OFF operation) of each of a supply of the cooling gas and a supply of the purge gas (that is, it is possible to switch between the supply of the cooling gas and a stop of the supply of the cooling gas and between the supply of the purge gas and a stop of the supply of the purge gas). Further, either the cooling gas or the purge gas can be selected and supplied into the heat insulator 33.

As the cooling gas, for example, a gas such as industrial nitrogen gas in a normal temperature (room temperature) and air (artificial air) may be used. Further, as the purge gas, a gas such as pure nitrogen gas for a semiconductor process and normal nitrogen gas may be used. Therefore, since heating or cooling of the cooling gas (or the purge gas) can be omitted, it is possible to apply the cooling gas (or the purge gas) at a low cost. The industrial nitrogen gas can be prepared by vaporizing industrial liquefied nitrogen, and such a gas can be used as the purge gas because of its high purity.

For example, the introduction pipe 45a may be configured as a part of the supply pipe 46. In such a case, the supply pipe 46 serves as a flexible portion with a sufficient flexibility, and the introduction pipe 45a serves as a non-flexible portion (that is, a portion without a sufficient flexibility) through which the movable end of the supply pipe 46 and the rotator 42 are connected.

A controller 51 described later is connected to the rotator 42, the boat elevator 43, the MFCs 26a through 26d and the valves 28a through 28d of the gas supply structure 23, the conductance variable valve 36, the MFCs 48a and 48b and the valves 49a and 49b of the cooling gas supplier 44 so as to control operations thereof. For example, the controller 51 is constituted by a microprocessor (computer) including a CPU (Central Processing Unit), and is configured to control operations of the process module 2.

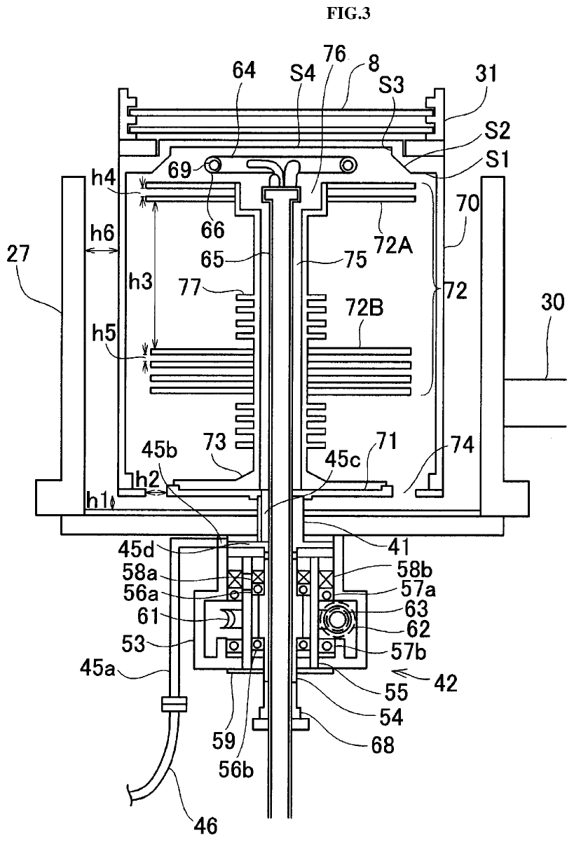

The heat insulator 33 and the rotator 42 will be described in detail with reference to FIG. 3. The rotator 42 includes a casing 53. The casing 53 is of a substantially cylindrical shape with an open upper end and a closed lower end. The casing 53 is provided at a lower surface of the lid 32. An inner shaft 54 of a thin and elongated cylindrical shape is arranged inside the casing 53. An outer shaft 55 of a cylindrical shape is arranged inside the casing 53. A diameter of the outer shaft 55 is set to be greater than an outer diameter of the inner shaft 54. In addition, the outer shaft 55 may be rotatably supported by a pair of inner bearings 56a and 56b interposed between the outer shaft 55 and the inner shaft 54 and a pair of outer bearings 57a and 57b interposed between the outer shaft 55 and the casing 53. The inner bearings 56a and 56b constitute a vertically arranged pair, and the outer bearings 57a and 57b constitute another vertically arranged pair.

Magnetic fluid seals 58a and 58b serving as sealing structures are provided at the inner bearing 56a and the outer bearing 57a, respectively. A cap 59 configured to seal a lower end portion of the outer shaft 55 is fixed to a lower surface of a closing wall of the casing 53. It is possible to maintain the airtightness between the rotating shaft 41 and the lid 32 by the magnetic fluid seals 58a and 58b. For example, a sealed structure for the casing 53 is constituted by the magnetic fluid seals 58a and 58b and the cap 59. A worm wheel 61 is fixed on an outer circumference of the outer shaft 55 between the outer bearing 57a and the outer bearing 57b. A worm shaft 63 which is rotationally driven by an electric motor 62 is engaged with the worm wheel 61.

The port 45b is provided on the casing 53 at a portion facing the process chamber 21 rather than a portion facing the magnetic fluid seals 58a and 58b. Therefore, a space 45d between the casing 53 and the rotating shaft 41 communicates with the introduction pipe 45a through the port 45b at the portion facing the process chamber 21 rather than the portion facing the magnetic fluid seals 58a and 58b. Further, the space 45d and the inside of the heat insulator 33 communicate with each other through the hole 45c provided in the rotating shaft 41.

A sub-heater 64 serving as a second heating structure (second heating apparatus) capable of heating the wafer 8 from thereunder in the process chamber 21 is inserted into an inner side of the inner shaft 54 so as to vertically pass therethrough. The sub-heater 64 may include a support column (which is a pillar) 65 extending in the vertical direction and a heat generator (which is a heat generating structure) 66 horizontally connected to the support column 65. The support column 65 is supported at a position of an upper end of the inner shaft 54 by a support structure 68 made of a heat resistant resin. Further, a lower end portion of the support column 65 is supported by the support (which is a support structure) 68 serving as a vacuum coupling (vacuum joint) via an O-ring at a position below a lower surface of the closing wall of the casing 53.

The heat generator 66 is of a substantially annular shape. Further, a diameter of the heat generator 66 is set to be smaller than an outer diameter of the wafer 8. The heat generator 66 is connected to and supported by the support column 65 so as to be parallel to the wafer 8. A heater wire constituting a heating element 69 (which is a resistance heating element of a coil shape) is sealed inside the heat generator 66. For example, the heating element 69 is made of a material such as a Fe—Cr—Al alloy and molybdenum disilicide.

The rotating shaft 41 of a cylindrical shape provided with a flange at a lower end thereof is fixed to an upper surface of the outer shaft 55. A through-hole through which the sub-heater 64 penetrates is provided at a center of the rotating shaft 41. A receiving plate (which is a receiving structure) 71 of a disk shape is fixed at an upper end portion of the rotating shaft 41 with a predetermined interval (gap) h1 from the lid 32. A through-hole through which the sub-heater 64 penetrates is provided at a center of the receiving plate 71. It is preferable that the interval h1 is set to be within a range from 2 mm to 10 mm. When the interval h1 is less than 2 mm, components related thereto may come into contact with each other when the boat 31 is being rotated, and a gas exhaust speed in a case 70 of a cylindrical shape (which will be described later) may decrease due to a decrease in conductance. When the interval h1 is greater than 10 mm, a large amount of a process gas may enter the case 70.

For example, the receiving plate 71 is made of a metal material such as stainless steel. The case 70 and a holder 73 serving as a heat insulation plate holder configured to hold (or support) a plurality of heat insulation plates 72 are placed on an upper surface of the receiving plate 71. For example, the heat insulator 33 is constituted by the receiving plate 71, the holder 73, the case 70 and the heat insulation plates 72. For example, the case 70 is of a cylindrical shape with a closed upper end such that the sub-heater 64 can be accommodated therein. As shown in FIG. 3, an exhaust hole 74 with a hole diameter h2 is provided in a region between the holder 73 and the case 70 when viewed from above. An inner atmosphere of the case 70 can be exhausted through the exhaust hole 74. For example, a plurality of exhaust holes including the exhaust hole 74 may be provided along a concentric circle of the receiving plate 71 at a regular interval. It is preferable that the hole diameter h2 is set to be within a range from 10 mm to 40 mm. When the hole diameter h2 is less than 10 mm, the gas exhaust speed in the case 70 may decrease due to the decrease in the conductance. When the hole diameter h2 is greater than 40 mm, a load-bearing strength of the receiving plate 71 may be lowered, and thus the receiving plate 71 may be damaged.

As shown in FIG. 3, the holder 73 is of a cylindrical shape. A through-hole 75 through which the sub-heater 64 penetrates is provided at a center of the holder 73. The introduction pipe 45a is connected to the port 45b provided on a side surface of the casing 53. The port 45b communicates with a through-hole penetrating the lid 32 (the rotating shaft 41) and the receiving plate 71, and passes through the through-hole penetrating the lid 32 and the receiving plate 71 so as to be open toward the through-hole 75. That is, the introducer 45 and the through-hole 75 are fluidically in communication with each other.

A lower end of the holder 73 is of an outward flange shape whose outer diameter is smaller than that of the receiving plate 71. A diameter of an upper end of the holder 73 is set to be greater than that of a column portion of the holder 73 between the upper and lower ends of the holder 73 such that a discharge port (which is an ejection port) 76 for the purge gas and the cooling gas is defined. A diameter of the through-hole 75 is set to be greater than a diameter of an outer wall of the support column 65 of the sub-heater 64. With such a configuration, an annular space is defined (provided) between the holder 73 and the support column 65. A cylindrical space including the annular space may serve as a gas supply path (first flow path) through which the cooling gas and the purge gas are supplied into the heat insulator 33.

For example, the holder 73 is made of a heat resistant material such as quartz and silicon carbide (SiC). The holder 73 is formed such that a connection surface between the outward flange shape at the lower end thereof and the column portion thereof is curved. With such a configuration, it is possible to suppress a concentration of stress on the connection surface, and it is also possible to increase a strength of the holder 73. Further, by setting the connection surface smooth (that is, curved), it is possible to suppress an occurrence of stagnation of the purge gas in the case 70 without interfering with a flow of the purge gas.

For example, the purge gas is supplied from the discharge port 76 toward an upper inner portion of the case 70. By configuring the discharge port 76 as an annular opening, it is possible to uniformly supply the purge gas to an upper end of the case 70 and an entire circumferential direction of a radial direction of an annular plane. Further, by setting the diameter of the discharge port 76 to be greater than the diameter of the column portion, it is possible to supply the purge gas in a wide range in the radial direction inside the case 70 and toward an upper space inside the case 70. By actively purging the vicinity of an upper end portion (ceiling) of the case 70 (in particular, a portion where the heat generator 66 is installed) with the purge gas in a manner described above, it is possible to prevent (suppress) the heat generator 66 from being exposed to the process gas. The purge gas supplied through the discharge port 76 is exhausted to an outside of the case 70 through a second flow path (which is a space between the holder 73 and an inner wall of the case 70).

A plurality of reflective plates including a reflective plate 72A and a plurality of thermal insulation plates including a thermal insulation plate 72B, which constitute the heat insulation plates 72, are provided on the column portion of the holder 73. Hereinafter, the plurality of reflective plates including the reflective plate 72A may also be simply referred to as “reflective plates 72A”, and the plurality of thermal insulation plates including the thermal insulation plate 72B may also be simply referred to as “thermal insulation plates 72B”. For example, the reflective plates 72A are fixedly attached by welding to an upper portion of the holder 73. For example, the thermal insulation plates 72B are fixedly attached by welding to a middle portion of the holder 73. A plurality of support shelves including a support shelf 77 are provided on the holder 73 above and below the thermal insulation plates 72B. Hereinafter, the plurality of support shelves including the support shelf 77 may also be simply referred to as “support shelves 77”. The support shelves 77 extend outwardly and horizontally from an outer wall of the column portion of the holder 73. With such a configuration, the support shelves 77 can support (or hold) the thermal insulation plates 72B while the thermal insulation plates 72B are horizontally oriented with their centers aligned with one another in a multistage manner. A predetermined interval (gap) h3 is provided between the reflective plate 72A and the thermal insulation plate 72B. More specifically, the interval h3 is provided between a lowermost reflective plate among the reflective plates 72A and an uppermost thermal insulation plate among the thermal insulation plates 72B. It is preferable that the interval h3 is set to be within a range from 50 mm to 300 mm.

The reflective plate 72A is of a disk shape whose diameter is smaller than that of the wafer 8. For example, the reflective plate 72A is made of a material such as opaque quartz. The reflective plates 72A are provided in the upper portion of the support shelves 77 with a predetermined interval (gap) h4 therebetween. It is preferable that the interval h4 is set to be within a range from 2 mm to 10 mm. When the interval h4 is less than 2 mm, the gas such as the process gas may remain between the reflective plates 72A. When the interval h4 is greater than 10 mm, a heat reflection performance may deteriorate.

The thermal insulation plate 72B is of a disk shape whose outer diameter is smaller than that of the wafer 8. Preferably, the thermal insulation plate 72B is made of a material whose heat capacity and thermal conductivity are small (that is, for example, a material such as quartz, silicon (Si) and silicon carbide (SiC)). According to the present embodiments, four thermal insulation plates 72B are supported by four support shelves among the support shelves 77 located below with a predetermined interval (gap) h5 therebetween. It is preferable that the interval h5 is set to be equal to or greater than 2 mm. When the interval h5 is less than 2 mm, the gas such as the process gas may remain between the thermal insulation plates 72B.

The number of the reflective plates 72A and the number of the thermal insulation plates 72B are not limited to the numbers described above. For example, it is preferable that the number of the thermal insulation plates 72B is equal to or greater than the number of the reflective plates 72A. By providing the reflective plate 72A above and providing the thermal insulation plate 72B below in a manner described above, it is possible to reflect the radiant heat from the sub-heater 64 by the reflective plate 72A, and it is also possible to insulate the radiant heat from the heater 19 and the sub-heater 64 at a location away from the wafer 8 by the thermal insulation plate 72B. With such a configuration, it is possible to improve a temperature responsiveness of the wafer 8, and it is also possible to shorten a temperature elevation time (which is a heating-up time).

The boat 31 is provided on an upper surface of the case 70. A groove (recess) is provided in an outer circumference of the upper surface of the case 70 over an entire circumference thereof. A bottom plate (which is of a ring shape) of the boat 31 is placed on the groove. With such a configuration, it is possible to rotate the case 70 and the boat 31 without rotating the sub-heater 64.

The upper end of the case 70 is of a convex shape. An inner surface (inner wall) of the upper end of the case 70 includes a horizontal plane S1 protruding inward from an inner wall surface thereof, an inclined plane S2 which continues with the horizontal plane S1, a vertical plane S3 which continues with the inclined plane S2 in the vertical direction and a horizontal plane S4 which continues with the vertical plane S3. That is, a connection portion (corner portion) (that is, the inclined plane S2) which connects the horizontal plane S1 of a convex shape to the vertical plane S3 is of a taper shape, and a cross-sectional area of the connection portion (inclined plane S2) of the case 70 is gradually reduced toward the upper portion of the case 70 when viewed from above. Further, a connection portion of the vertical plane S3 and the horizontal plane S4 is a curved surface. With such a configuration, it is possible to improve a flow of the gas into the case 70, and thus it is possible to prevent (suppress) the gas from staying in the case 70 of the convex shape. The purge gas supplied through the discharge port 76 flows in a circumferential direction by hitting the inner wall of the upper surface of the case 70, and then flows downward along a sidewall of the inside of the case 70. Therefore, the purge gas may easily flow downward inside the case 70. That is, the purge gas may flow downward in the second flow path. Further, since a portion of the case 70 (which is below a placement portion for the boat 31) can be formed with a thickness greater than a thickness of a circumferential portion of the case 70 by the horizontal plane S1, it is possible to increase a strength of the case 70.

The heat generator 66 is provided in a region between an upper end of the support column 65 and the inner wall of the upper surface of the case 70. Preferably, at least a portion of the heat generator 66 is provided to be located between lowermost and uppermost ends of the inclined plane S2. That is, the heat generator 66 is provided to be accommodated in a region between a contact point of the horizontal plane S1 and the inclined plane S2 and a contact point of the inclined plane S2 and the vertical plane S3 in the vertical direction.

According to the present embodiments, as described above, the heat insulator 33 is illustrated to include the case 70 for convenience of description. However, the thermal insulation is mainly performed in a region below the sub-heater 64, that is, in the heat insulation plates 72. Therefore, the heat insulation plates 72 alone may be referred to as the “heat insulator 33”. In such a case, the sub-heater 64 is provided between the boat 31 and the heat insulator 33.

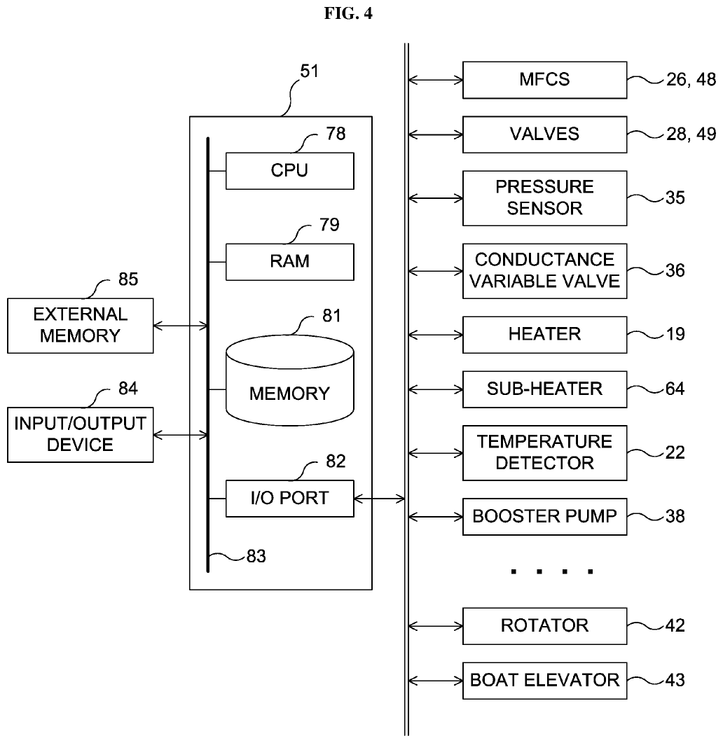

As shown in FIG. 4, the controller 51 is electrically connected to the components of the substrate processing apparatus 1 such as the MFCs 26a, 26b, 26c, 26d, 48a and 48b, the valves 28a, 28b, 28c, 28d, 49a and 49b, the pressure sensor 35, the conductance variable valve 36, the booster pump 38, the heater 19, the sub-heater 64, the temperature detector 22, the rotator 42 and the boat elevator 43, and is configured to automatically control the components electrically connected thereto. For example, the controller 51 is constituted by a computer including a CPU (Central Processing Unit) 78, a RAM (Random Access Memory) 79, a memory 81 and an I/O port (input/output port) 82. The RAM 79, the memory 81 and the I/O port 82 may exchange data with the CPU 78 through an internal bus 83. The I/O port 82 is connected to the components described above. For example, an input/output device 84 constituted by a component such as a touch panel is connected to the controller 51.

For example, the memory 81 is configured by a component such as a flash memory and a hard disk drive (HDD). For example, a control program configured to control operations of the substrate processing apparatus 1 or a program (that is, a recipe such as a process recipe and a cleaning recipe) that causes the components of the substrate processing apparatus 1 to perform the substrate processing such as a film-forming process in accordance with process conditions may be readably stored in the memory 81. The RAM 79 functions as a memory area (work area) where a program or data read by the CPU 78 is temporarily stored.

The CPU 78 is configured to read the control program from the memory 81 and execute the read control program. In addition, the CPU 78 is configured to read the recipe from the memory 81 in accordance with an operation command inputted from the input/output device 84. According to the contents of the read recipe, the CPU 78 is configured to be capable of controlling the components of the substrate processing apparatus 1.

The controller 51 may be embodied by installing the above-described program permanently stored in an external memory 85 into the computer. For example, the external memory 85 may include a semiconductor memory such as a USB memory and a memory card, an optical disk such as a CD and a DVD and a hard disk drive (HDD). The memory 81 or the external memory 85 may be embodied by a non-transitory computer readable and tangible recording medium. Hereafter, the memory 81 and the external memory 85 may be collectively or individually referred to as a “recording medium”. Instead of the external memory 85, a communication structure such as the Internet and a dedicated line may be used for providing the program to the computer.

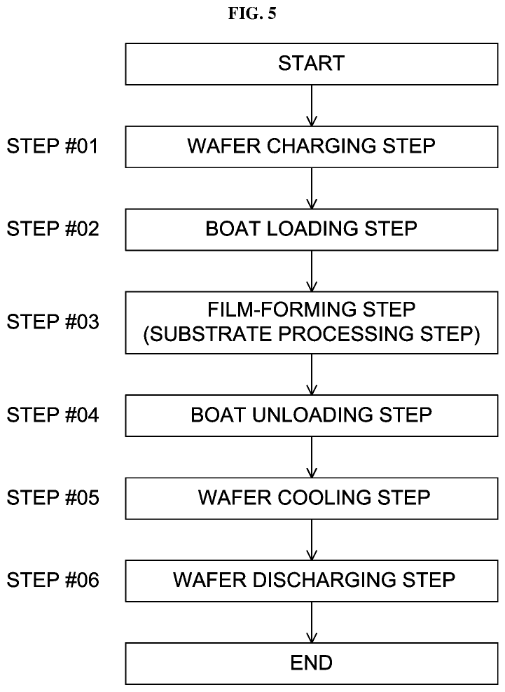

Subsequently, a process (film-forming process) (that is, the substrate processing) of forming a film on the substrate (that is, the wafer 8) by using the substrate processing apparatus 1 described above will be described with reference to a flow chart shown in FIG. 5. The film-forming process will be described by way of an example in which the SiO₂ film is formed on the wafer 8 by supplying DCS (SiH₂Cl₂:dichlorosilane) gas serving as the source gas and O₂ (oxygen) gas serving as the reactive gas onto the wafer 8. Further, in the present specification, the term “process temperature” refers to a temperature of the wafer 8 or an inner temperature of the process chamber 21, and the term “process pressure” refers to the inner pressure of the process chamber 21. In the following description, operations of the components constituting the substrate processing apparatus 1 are controlled by the controller 51.

<Wafer Charging Step and Boat Loading Step>

The gate valve 15 is opened and the wafer 8 is transferred into the boat 31. When the wafers 8 are transferred (charged) into the boat 31 (wafer charging step, that is, STEP #01), the gate valve 15 is closed. Then, the boat 31 is loaded into the process chamber 21 by the boat elevator 43 (boat loading step, that is, STEP #02). With the boat 31 loaded, the lower end opening of the reaction tube 18 is airtightly closed (or sealed) by the lid 32.

<Pressure Adjusting and Temperature Adjusting Step>

The booster pump 38 vacuum-exhausts (decompresses and exhausts) the process chamber 21 such that the inner pressure of the process chamber 21 reaches and is maintained at a predetermined pressure (vacuum degree). An inner atmosphere of the process chamber 21 flows linearly or substantially linearly through the exhaust pipe 34, and is exhausted through the booster pump 38. The inner pressure of the process chamber 21 is measured by the pressure sensor 35, and conductance variable valve 36 is feedback-controlled based on pressure information measured by the pressure sensor 35. In the present step, the heater 19 heats the process chamber 21 from a periphery of the process chamber 21 and the sub-heater 64 heats the process chamber 21 from a lower portion of the process chamber 21 such that the temperature of the wafer 8 accommodated in the process chamber 21 reaches and is maintained at a predetermined temperature. It is possible to efficiently heat the process chamber 21 by being heated from both from the periphery and the lower portion of the process chamber 21. When heating the process chamber 21, a state of the electric conduction to the heater 19 and the sub-heater 64 is feedback-controlled based on temperature information detected by the temperature detector 22 such that a desired temperature distribution of the inner temperature of the process chamber 21 is obtained. Further, the boat 31 and the wafers 8 accommodated in the boat 31 are rotated by the rotator 42.

<Film-forming Step>

A film-forming step (that is, STEP #03) is performed by performing a cycle including a source gas supply step, a source gas exhaust step, a reactive gas supply step and a reactive gas exhaust step.

<Source Gas Supply Step>

When the inner temperature of the process chamber 21 is stabilized at a process temperature set in advance, the DCS gas is supplied to the wafers 8 in the process chamber 21. After a flow rate of the DCS gas is adjusted (controlled) to a desired flow rate by the MFC 26a, the source gas whose flow rate is adjusted is supplied into the process chamber 21 through the gas supply pipe 25a and the nozzle 29a. In parallel with a supply of the DCS gas, that is, while the opening of the reaction tube 18 is closed by the lid 32, the cooling gas supplier 44 supplies the purge gas whose flow rate is adjusted (controlled) to a desired flow rate by the MFC 48b into the heat insulator 33 from the discharge port 76 via the gas supply pipe 47b, the gas supply pipe 47a, the supply pipe 46, the introducer 45 and the through-hole 75. The purge gas is supplied (sprayed) directly onto a ceiling (that is, the closed upper end) of the case 70 and diffuses in a circumferential direction along the ceiling. Then, the purge gas flows downward along a circumferential surface, and then is supplied into the process chamber 21 through the exhaust hole 74.

<Source Gas Exhaust Step>

Subsequently, the supply of the DCS gas is stopped, and the inner atmosphere of the process chamber 21 is vacuum-exhausted by the booster pump 38. The DCS gas in the process chamber 21 flows linearly or substantially linearly through the exhaust pipe 34 and is exhausted through the booster pump 38. When vacuum-exhausting the inner atmosphere of the process chamber 21, N₂ gas serving as the inert gas may be supplied through the inert gas supplier into the process chamber 21 (purge by the inert gas).

<Reactive Gas Supply Step>

Subsequently, the O₂ gas is supplied to the wafers 8 in the process chamber 21. After a flow rate of the O₂ gas is adjusted (controlled) to a desired flow rate by the MFC 26b, the reactive gas whose flow rate is adjusted is supplied into the process chamber 21 through the gas supply pipe 25b and the nozzle 29b.

<Reactive Gas Exhaust Step>

Subsequently, the supply of the O₂ gas is stopped, and the inner atmosphere of the process chamber 21 is vacuum-exhausted by the booster pump 38. The O₂ gas in the process chamber 21 flows linearly or substantially linearly through the exhaust pipe 34 and is exhausted through the booster pump 38. When vacuum-exhausting the inner atmosphere of the process chamber 21, the N₂ gas serving as the inert gas may be supplied through the inert gas supplier into the process chamber 21 (purge by the inert gas). However, the purge gas is continuously supplied into the heat insulator 33 in the source gas exhaust step, the reactive gas supply step and the reactive gas exhaust step.

By performing the cycle including the four steps described above a predetermined number of times (once or more), it is possible to form the SiO₂ film with a predetermined composition and a predetermined thickness on the wafer 8 (STEP #03).

<Boat Unloading Step, Wafer Cooling Step and Wafer Discharging Step>

After the film with a predetermined thickness is formed on the wafer 8, the N₂ gas is supplied through the inert gas supplier. Thereby, the inner atmosphere of the process chamber 21 is replaced with the N₂ gas, and the inner pressure of the process chamber 21 is returned to an atmospheric pressure (normal pressure). Thereafter, the lid 32 is lowered by the boat elevator 43, and the boat 31 is unloaded out of the reaction tube 18 (boat unloading step, that is, STEP #04).

After the boat 31 is unloaded, that is, while the opening of the reaction tube 18 is not closed by the lid 32, a cooling process for the wafer 8 and the heat insulator 33 is performed (wafer cooling step, that is, STEP #05). The cooling gas is supplied to the wafer 8 from a cooling gas supply structure (not shown). In parallel with the cooling process for the wafer 8, the cooling gas suppler 44 supplies the cooling gas whose flow rate is adjusted (controlled) to a desired flow rate by the MFC 48a into the heat insulator 33 from the discharge port 76 via the gas supply pipe 47a, the supply pipe 46, the introducer 45 and the through-hole 75. The cooling gas is supplied (sprayed) directly onto the ceiling (that is, the closed upper end) of the case 70 and diffuses in the circumferential direction along the ceiling. Then, the cooling gas flows downward along the circumferential surface, and then is supplied into the transfer chamber 5 through the exhaust hole 74 while cooling the heat insulation plates 72 and the case 70.

For example, the cooling gas supplied into the heat insulator 33 is the N₂ gas in the normal temperature. For example, the flow rate of the cooling gas is set to be equal to that of the purge gas. On the other hand, the flow rate of the cooling gas may be increased to an extent that the particles are not stirred up inside the transfer chamber 5. In such a case, a mass flow rate of the cooling gas is set to be greater than a mass flow rate of the purge gas.

When the wafers 8 and the heat insulator 33 are cooled down to a predetermined temperature, the transfer structure 9 transfers (discharges) the wafers (which are processed) 8 charged in the boat 31 to the pod 12 (wafer discharging step, that is, STEP #06). The wafers 8 stored in the pod 12 are transferred (unloaded) out of the substrate processing apparatus 1. Thereby, the film-forming process is completed.

In the series of processes (steps) using the substrate processing apparatus 1, the valves 49a and 49b may be interlocked and the supply of cooling gas or the supply of the purge gas may be forcibly stopped when the substrate processing apparatus 1 is stopped urgently or when a maintenance door of the transfer chamber 5 is opened. In such a case, the controller 51 functions as an interlock controller. By forcibly stopping the supply of the cooling gas or the supply of the purge gas, it is possible to prevent the gas from leaking out of the substrate processing apparatus 1 and it is also possible to prevent an increase in a pressure such as the inner pressure of the process chamber 21.

For example, the process conditions when forming the SiO₂ film on the wafer 8 are as follows:
The process temperature (the temperature of the wafer 8): from 300° C. to 700° C.;
The process pressure (the inner pressure of the process chamber 21): from 1 Pa to 4,000 Pa;
The flow rate of the DCS gas: from 100 sccm to 10,000 sccm;
The flow rate of the O₂ gas: from 100 sccm to 10,000 sccm; and
The flow rate of the N₂ gas: from 100 sccm to 10,000 sccm;

By setting each process condition to a value within each range described above, it is possible to appropriately perform the film-forming process. Further, in the present specification, a notation of a numerical range such as “from 1 Pa to 4,000 Pa” means that a lower limit and an upper limit are included in the numerical range. Therefore, for example, a numerical range “from 1 Pa to 4,000 Pa” means a range equal to or higher than 1 Pa and equal to or lower than 4,000 Pa. The same also applies to other numerical ranges described in the present specification.

According to the present embodiments, it is possible to obtain one or more of the following effects.

According to the present embodiments, in the cooling process (wafer cooling step) after the film is formed on the wafer 8, the cooling gas is supplied from the discharge port 76 into the heat insulator 33 through the introducer 45 and the through-hole 75. The cooling gas is circulated such that heat insulation plates 72 and the case 70 can be cooled inside the heat insulator 33.

Therefore, it is possible to shorten a cooling time of the heat insulator 33 whose heat capacity is greater than that of the wafer 8. As a result, it is possible to shorten an overall time of the wafer cooling step process and the substrate processing, and it is also possible to improve the throughput.

Further, the cooling gas is supplied (sprayed) directly onto the closed upper end (which is greatly affected by the radiant heat from the process chamber 21) of the case 70, it is possible to further improve a cooling efficiency of the heat insulator 33. In addition, since the mass flow rate of the cooling gas can be set to be greater than the mass flow rate of the purge gas, it is possible to more further improve the cooling efficiency of the heat insulator 33.

During the film-forming step, that is, while the boat 31 is inserted into the process chamber 21, the purge gas is supplied into the heat insulator 33 to purge the inside (inner space or inner atmosphere) of the heat insulator 33. Therefore, it is possible to prevent the source gas and the reactive from flowing (entering) into the heat insulator 33, and it is also possible to prevent a film from being formed on the heat insulation plates 72 or on the sub-heater 64.

Further, the supply pipe 46 is provided with the sufficient flexibility, and is configured to be capable of being connected to the gas supply pipe 47a and the introduction pipe 45a fixed to the rotator 42 in a state where the supply pipe 46 is bent. Therefore, since the supply pipe 46 can be moved along with the boat 31 when the boat 31 is elevated or lowered, it is possible to maintain the fluid communications with the introducer 45 and the gas supply pipe 47a regardless of the position of the boat 31.

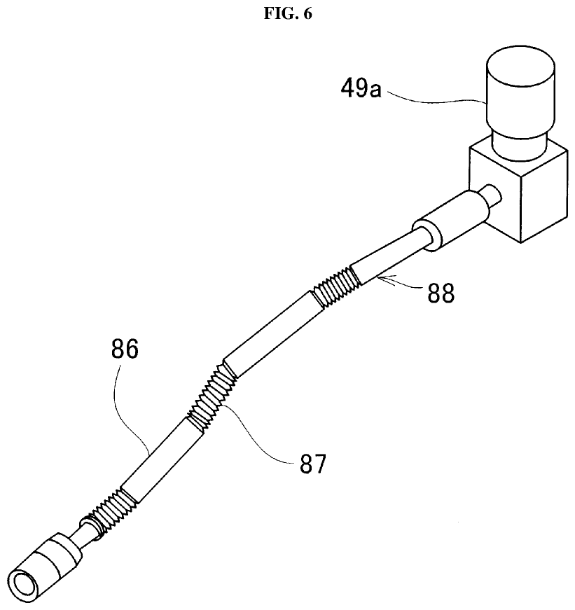

Further, according to the present embodiments, the supply pipe 46 is made of the synthetic resin containing fluorine. However, a configuration of the supply pipe 46 is not limited thereto. For example, as in a modified example shown in FIG. 6, by alternately connecting a non-flexible metal pipe 86 and a flexible metal bellows 87, it is possible to provide a supply pipe 88, a part of which is flexible.

Even when the supply pipe 88 is used, it is possible to obtain substantially the same effects as in a case of using the supply pipe 46. In addition, it is possible to improve a durability of the supply pipe 88 to be greater than that of the supply pipe 46.

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof.

For example, the embodiments described above are described by way of an example in which the DCS gas is used as the source gas. However, the technique of the present disclosure is not limited thereto. Instead of or in addition to the DCS gas, for example, an inorganic halosilane source gas such as HCDS (Si₂Cl₆:hexachlorodisilane) gas, MCS (SiH₃Cl:monochlorosilane) gas and TCS (SiHCl₃:trichlorosilane) gas may be used as the source gas. Instead of or in addition to the DCS gas, for example, an amino-based (amine-based) silane source gas free of halogen such as 3DMAS (Si[N(CH₃)₂]₃H:trisdimethylaminosilane) gas and BTBAS (SiH₂[NH(C₄H₉)]₂:bis(tertiarybutylamino) silane) gas may be used as the source gas. Instead of or in addition to the DCS gas, for example, an inorganic silane source gas free of halogen such as MS (SiH₄:monosilane) gas and DS (Si₂H₆:disilane) gas may be used as the source gas.

For example, the embodiments described above are described by way of an example in which the SiO₂ film is formed. However, the technique of the present disclosure is not limited thereto. For example, instead of the gases described above or in addition to the gases described above, a nitrogen (N)-containing gas (nitriding gas) such as ammonia (NH₃) gas, a carbon (C)-containing gas such as propylene (C₃H₆) gas and a boron (B)-containing gas such as boron trichloride (BCl₃) gas may be used to form various films such as silicon nitride (SiN) film, a silicon oxynitride (SiON) film, a silicon oxycarbonitride (SiOCN) film, a silicon oxycarbide (SiOC) film, a silicon carbonitride (SiCN) film, a silicon boronitride (SiBN) film and a silicon borocarbonitride (SiBCN) film. When forming the various films described above, process conditions related thereto may be substantially the same as those of the film-forming process according to the embodiments described above, and it is possible to obtain substantially the same effects as those of the embodiments described above.

For example, the technique of the present disclosure may also be preferably applied to form, on the wafer 8, a film containing a metal element (that is, a metal-based film) such as titanium (Ti), zirconium (Zr), hafnium (Hf), tantalum (Ta), niobium (Nb), aluminum (Al), molybdenum (Mo) and tungsten (W).

For example, the embodiments described above are described by way of an example in which the film is deposited on the wafer 8. However, the technique of the present disclosure is not limited thereto. For example, the technique of the present disclosure may also be preferably applied when a process such as an oxidation process, a diffusion process, an annealing process and an etching process is performed on the wafer 8 or on the film formed on the wafer 8.

Further, the embodiment described above and modified examples described above may be appropriately combined. The process conditions of each combination thereof may be substantially the same as those of the embodiments described above.

For example, the embodiment described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

Even when the substrate processing apparatus including the cold wall type process furnace is used, it is possible to perform each process by using process procedures and process conditions substantially the same as those of the embodiments described above or the modified examples described above. Even in such a case, it is possible to obtain substantially the same effects as in the embodiments described above or the modified examples described above.

According to some embodiments of the present disclosure, it is possible to shorten the cooling time of the heat insulator.

What is claimed is:

1. A substrate processing apparatus comprising:
a process vessel in which a substrate is processed;
a lid capable of closing an opening provided at a lower portion of the process vessel;
an elevator capable of elevating and lowering the lid;
a heat insulator provided between the lid and the substrate and comprising a case of a cylindrical shape with a closed upper end; and
a cooling gas supplier configured to purge an inside of the heat insulator by supplying a purge gas through a discharge port in the case while the opening is closed by the lid, and to cool the heat insulator by supplying a cooling gas through the discharge port while the opening is not closed by the lid.

2. The substrate processing apparatus of claim 1, wherein the cooling gas supplier comprises:
an introducer penetrating the lid and configured to introduce the purge gas and the cooling gas into the heat insulator;
a movable supply pipe fluidically in communication with the introducer and configured to supply the purge gas into the introducer; and
a control valve to perform a turn-on and turn-off operation for each of a supply of the purge gas and a supply of the cooling gas.

3. The substrate processing apparatus of claim 2, wherein at least a part of the supply pipe is flexible.

4. The substrate processing apparatus of claim 1, wherein at least a part of the cooling gas supplier is fixed to the lid and configured to be elevated or lowered together with the lid by the elevator.

5. The substrate processing apparatus of claim 1, wherein a mass flow rate of the cooling gas is set to be greater than a mass flow rate of the purge gas.

6. The substrate processing apparatus of claim 1, further comprising:
a transfer chamber in communication with the opening of the process vessel and accommodating the elevator provided therein, wherein a substrate retainer is inserted into the transfer chamber when the substrate retainer is lowered; and
an interlock controller configured to be capable of forcibly stopping a supply of the purge gas and a supply of the cooling gas when the substrate processing apparatus is stopped urgently or when a maintenance door of the transfer chamber is opened.

7. The substrate processing apparatus of claim 1, wherein the purge gas comprises pure nitrogen gas and the cooling gas comprises nitrogen gas less pure than that of the pure nitrogen gas.

8. The substrate processing apparatus of claim 1, further comprising
a substrate retainer configured to be elevated or lowered together with the lid so as to be transferred into or out of the process vessel through the opening and configured to accommodate the substrate in the process vessel.

9. The substrate processing apparatus of claim 1, further comprising
a heater provided in the case and configured to heat an inside of the process vessel.

10. The substrate processing apparatus of claim 1, wherein the discharge port is open such that the cooling gas directly hits the closed upper end of the case.

11. The substrate processing apparatus of claim 2, further comprising:
a rotating shaft configured to support the heat insulator from thereunder and constituting at least a part of the introducer, wherein the rotating shaft is hollow; and
a rotator provided at the lid and configured to support the rotating shaft such that the rotating shaft is capable of being rotated,
wherein the inside of the heat insulator and an inside of the rotating shaft are fluidically in communication with each other.

12. The substrate processing apparatus of claim 11, wherein the rotator comprises:
a casing of a sealed structure; and
a seal configured to maintain an airtightness between the rotating shaft and the lid,
wherein the supply pipe is connected to a port provided at the casing.

13. The substrate processing apparatus of claim 12, wherein a space between the casing and the rotating shaft is in communication with the port at a portion of the casing facing the process vessel, and
the rotating shaft is provided with a hole through which an inside and an outside of the rotating shaft are in communication with each other.

14. The substrate processing apparatus of claim 11, wherein the supply pipe comprises:
a flexible portion comprising:
a fixed end configured to be unmovable and provided at an upstream portion of the supply pipe; and
a movable end configured to be elevated or lowered together with the lid by the elevator; and
a non-flexible portion configured to connect the movable end and the rotator.

15. The substrate processing apparatus of claim 3, wherein the supply pipe is provided by alternately connecting a flexible metal bellows and a non-flexible metal pipe.

16. The substrate processing apparatus of claim 3, wherein the supply pipe is made of a synthetic resin containing fluorine.

17. The substrate processing apparatus of claim 2, wherein the control valve is arranged in a gas box in which a flow rate controller or a valve for a process gas used to process the substrate is accommodated.

18. A substrate processing method comprising:
(a) purging an inside of a heat insulator provided between a lid and a substrate and comprising a case of a cylindrical shape with a closed upper end by supplying a purge gas through a discharge port in the case while an opening provided at a lower portion of a process vessel in which the substrate is processed is closed by the lid; and
(b) cooling the heat insulator by supplying a cooling gas through the discharge port while the opening is not closed by the lid.

19. A method of manufacturing a semiconductor device, comprising the substrate processing method of claim 18.

20. A non-transitory computer-readable recording medium storing a program that causes a substrate processing apparatus, by a computer, to perform a process comprising the substrate processing method of claim 18.
